(19) United States
(12) Patent Application Publication
(10) Pub. No.: US 2008/0232162 A1
(43) Pub. Date: Sep. 25, 2008

(54) One time programming cell structure and method of fabricating the same

(76) Inventors: Hing Poh Kuan, Singapore (SG); Kwang Ye Sim, Singapore (SG)

Correspondence Address: CHRISTIE, PARKER & HALE, LLP, PO BOX 7068, PASADENA, CA, 91109-7068, US

(21) Appl. No.: 11/728,221

(22) Filed: Mar. 23, 2007

(51) Int. Cl. G11C 17/08; H01L 21/8247; H01L 27/115

(52) U.S. Cl. 365/185.1; 257/322; 438/211; 257/E27.062; 257/E21.633; 257/E21.688

(57) ABSTRACT

A One Time Programming (OTP) cell structure, a method of fabricating an OTP structure, and a method of programming a OTP cell structure. The OTP structure comprises a semiconductor substrate; an n Metal-Oxide-Semiconductor (nMOS) programming structure formed on the substrate; wherein respective electrical contacts to a source of the nMOS programming structure and to a p-bulk of the substrate are separated for individual biasing of the source and the p-bulk of the substrate.

### FIELD OF INVENTION

The present invention relates broadly to a One Time Programming (OTP) cell structure, to a method of fabricating an OTP cell structure, and to a method of programming an OTP cell structure.

### BACKGROUND

OTPs cells are widely used for storing binary data, typically in Read Only Memory (ROM) integrated circuit memory cells. In a typical integrated circuit OTP, an n Metal Oxide Semiconductor (nMOS) programming field-effect transistor structure and a reading pMOS field-effect transistor structure, which share a floating gate (FG), are configured for programming and reading the OTP cell respectively. The “0” and “1” states of the OTP are distinguished based on the measured threshold voltage at the reading pMOS.

Typically, existing OTP cells are programmed based on Channel Hot Electron (CHE) programming methods. In a typical OTP cell's basic design, the contact to the source of the programming nMOS is electrically connected to the contact for biasing the p-bulk of the semiconductor substrate. The injection of hot electrons which ionize and produce electron-hole pairs, primarily in the drain of the programming nMOS with a multiplication factor, results in electrons being driven towards the semiconductor-to-oxide interface and the FG, thus programming the OTP cell. In addition to reliability issues as a result of the CHE programming, related primarily to the negative effects of the CHE current such as interface states and charge trapping in the oxide, the programming efficiency using CHE programming in existing memory cells is limited based on the underlying programming mechanism.

To improve programming efficiency, CHannel Initiated Secondary Electron (CHISEL) programming of memory cells has more recently been investigated. In CHISEL programming, similarly hot electrons ionize producing electron-hole pairs with a first multiplication factor. Furthermore, the produced holes are heated by a high field and ionize with a second multiplication factor, providing additional electrons that are driven toward the semiconductor-to-oxide interface for programming the FG of the memory cell.

A need therefore exists to provide an OTP cell structure suitable for CHISEL programming to take advantage of the improved programming efficiency expected for CHISEL programming methods.

### SUMMARY

In accordance with a first aspect of the present invention, there is provided a One Time Programming (OTP) cell structure comprising a semiconductor substrate; an n Metal-Oxide-Semiconductor (nMOS) programming structure formed on the substrate; wherein respective electrical contacts to a source of the nMOS programming structure and to a p-bulk of the substrate are separated for individual biasing of the source and the p-bulk of the substrate.

The nMOS programming structure may include Halo implantation for enhancing Channel Initiated Secondary Electron (CHISEL) programming of the OTP cell structure.

An outer metal layer design of the substrate may comprise a disconnection pattern between a metal contact portion for the source and a metal contact portion for the p-bulk of the substrate.

The source of the nMOS programming structure may be at ground potential.

The p-bulk of the substrate may be at a negative potential.

A threshold voltage of the nMOS programming structure of the OTP cell, in a programmed state, at a drain voltage of about 0.1V may be greater than about 3.5V for a programming gate voltage of about 5.25V, a programming drain voltage of about 4.25V, and a programming biasing voltage applied to the p-bulk of the substrate of about −1V, during programming of the nMOS programming structure.

The threshold voltage may be about 3.85V.

In accordance with a second aspect of the present invention, there is provided a method of fabricating a One Time Programming (OTP) cell structure, the method comprising the steps of providing a semiconductor substrate; forming an n Metal-Oxide-Semiconductor (nMOS) programming structure on the substrate; and forming an outer metal layer design of the substrate such that the metal layer design comprises a disconnection pattern between a metal contact portion for the source and a metal contact portion for the p-bulk of the substrate for individual biasing of the source and the p-bulk of the substrate.

The method may further comprise performing Halo implantation of the nMOS programming structure for enhancing Channel Initiated Secondary Electron (CHISEL) programming of the OTP cell structure.

In accordance with a third aspect of the present invention, there is provided a method of programming a One Time Programming (OTP) cell structure, the method comprising the steps of providing a semiconductor substrate; providing an n Metal-Oxide-Semiconductor (nMOS) programming structure on the substrate; and individually biasing a source of the nMOS programming structure and a p-bulk of the substrate during programming of the OTP.

The method may further comprise performing Halo implantation of the nMOS programming structure for enhancing Channel Initiated Secondary Electron (CHISEL) programming of the OTP cell structure.

### BRIEF DESCRIPTION OF THE DRAWINGS

The patent or application file contains drawings, FIGS. 1-5a-5i, executed in color. Copies of this patent or patent application publication with color drawing(s) will be provided by the Office upon request and payment of the necessary fee.

Embodiments of the invention will be better understood and readily apparent to one of ordinary skill in the art from the following written description, by way of example only, and in conjunction with the drawings, in which:

FIG. 1 shows a schematic cross-sectional drawing illustrating an OTP cell structure according to an example embodiment.

FIG. 2 shows respective plots of drain current at the nMOS as a function of the gate voltage V_{CG} for the OTP cell of FIG. 1.

FIG. 3 shows a schematic cross-sectional drawing illustrating the OTP cell structure of FIG. 1 in a read configuration.

FIG. 4 shows an overview of design of an OTP cell structure according to an example embodiment.

FIGS. 5a to i show respective mask layer layouts for the OTP cell design of FIG. 4.

FIG. 6 shows a flowchart illustrating a method of fabricating a One Time Programming (OTP) cell structure according to an example embodiment.

FIG. 7 shows a flowchart illustrating a method of programming a One Time Programming (OTP) cell structure according to an example embodiment.

### DETAILED DESCRIPTION

The example embodiments described provide an OTP cell design suitable for allowing CHISEL programming of the nMOS by providing the ability to separately bias the source of the nMOS and the p-bulk of the semiconductor substrate respectively. The described example embodiments, in allowing the CHISEL programming can facilitate that as the OTP cell device shrinks further in-line with demand for IC products and devices, the reliability of the OTP cell can be improved.

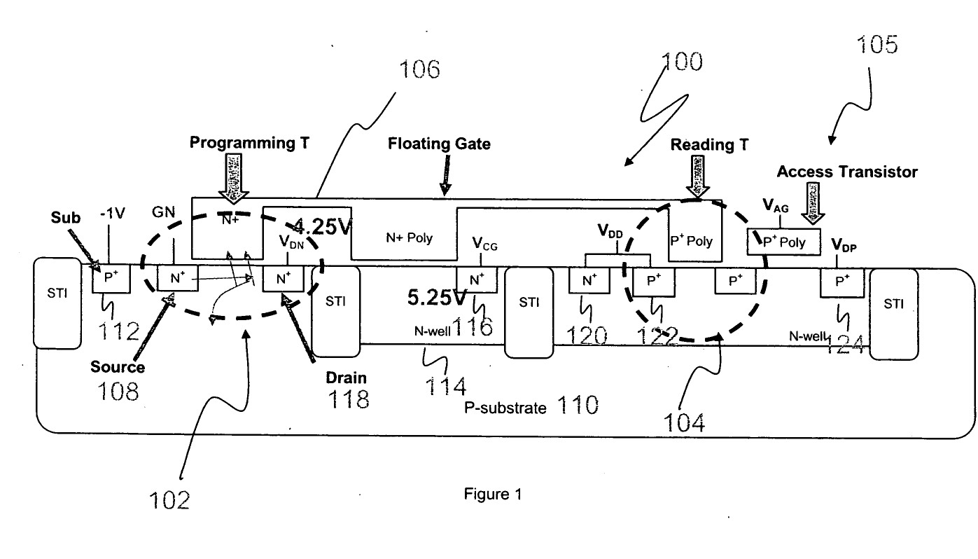

FIG. 1 shows a schematic cross-sectional drawing of an OTP cell structure 100 according to an example embodiment. The OTP cell 100 includes a programming nMOS 102, and a reading pMOS 104. The nMOS 102 and the pMOS 104 share a Floating Gate (FG) 106, formed, in the described example, from poly crystalline silicon.

During programming of the OTP cell 100, respective electrical contacts to the source 108 of the nMOS 102 and to the p-bulk substrate 110, via the p⁺ region 112, can be separately biased.

In contrast to the example embodiment shown in FIG. 1, in existing OTP cell designs, the source of the nMOS is electrically connected to the contact to the p-bulk of the substrate, for simultaneous, equal potential biasing. However, the inventors have recognized that allowing separate biasing of the p-bulk of the substrate 110 and of the source 108 of the nMOS 102 can facilitate CHISEL programming methods to be applied to the OTP cell design 100, thereby providing an improved programming efficiency compared to OTP cells capable only of CHE programming.

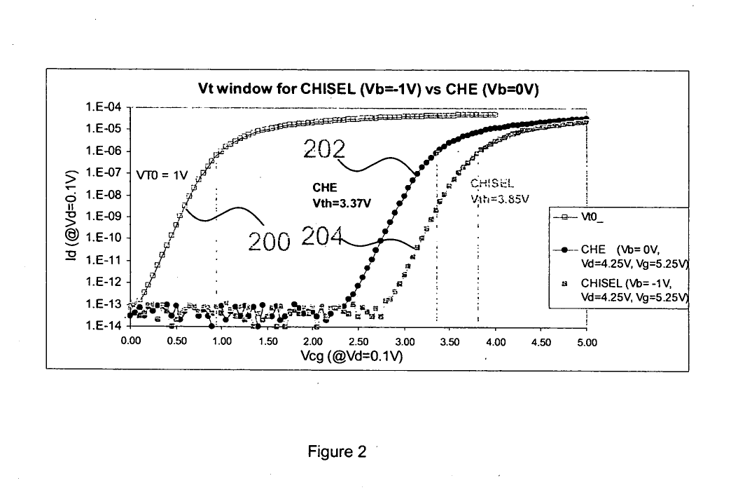

FIG. 2 shows respective plots of the drain current at the nMOS 102 (FIG. 1) as a function of the gate voltage V_{CG} at the n-well 114 (FIG. 1) pick-up 116 (FIG. 1) coupled to the FG 106 (FIG. 1). In FIG. 2, curve 200 corresponds to a UV erased cell according to an example embodiment, or before programming of the cell. Curve 202 corresponds to CHE programming, where both the source for the nMOS and the p-bulk of the substrate are biased at 0V. Curve 204 corresponds to CHISEL programming, where the source of the nMOS is kept at 0V, while the p-bulk of the substrate is separately biased at −1V. For both curves 202 and 204, the voltage V_{CG} at the n-well 114 (FIG. 1) pick-up 116 (FIG. 1) coupled to the FG 106 (FIG. 1) was 5.25V during programming, and the voltage V_{DN} applied to the drain 118 (FIG. 1) of the nMOS 102 (FIG. 1) was 4.25V during programming.

As can be seen from FIG. 2, for CHISEL programming, the example embodiment provides a larger Vₜ , window compared to CHE programming. More particular, where Vₜ for CHE programming is about 3.37V, the Vₜ for CHISEL programming is larger than 3.5V and in the particular example about 3.85V. This larger Vₜ window for CHISEL programming in the described example can be exploited such that a) programming may be performed at a lower gate voltage V_{CG} during the programming compared to CHE programming for a given Vₜ window size, b) for the same gate voltage V_{CG}, a better distinction between the “0” and the “1” states can be achieved, c) better reliability can be achieved by avoiding the negative effects of the CHE current such as interface traps generation at the drain side of the nMOS, and/or d) better retention performance of the programmed cell can be achieved due to the programmed Vₜ being higher.

The inventors have further recognized that for optimizing the CHISEL programming performance in the example embodiments, the nMOS transistor can be processed with Halo implantation, for example using Boron species, and/or varying the separate biasing of the p-bulk of the semiconductor substrate at different negative values. Experimental results showed that Halo implementation of Boron species of about 9×10¹² atoms/cm² may for example be used to improve the CHISEL programming performance in an example implementation. In such an example implementation, using Halo implantation can enhance the CHISEL programming efficiency. This can increase the programming speed and/or providing a higher Vₜ to the cell which in turn provides an even larger Vₜ window. In another example implementation, without Halo implantation, a higher CHISEL programming efficiency may be achieved by making the p⁺ substrate biasing more negative e.g. −1.5V, −2V etc.

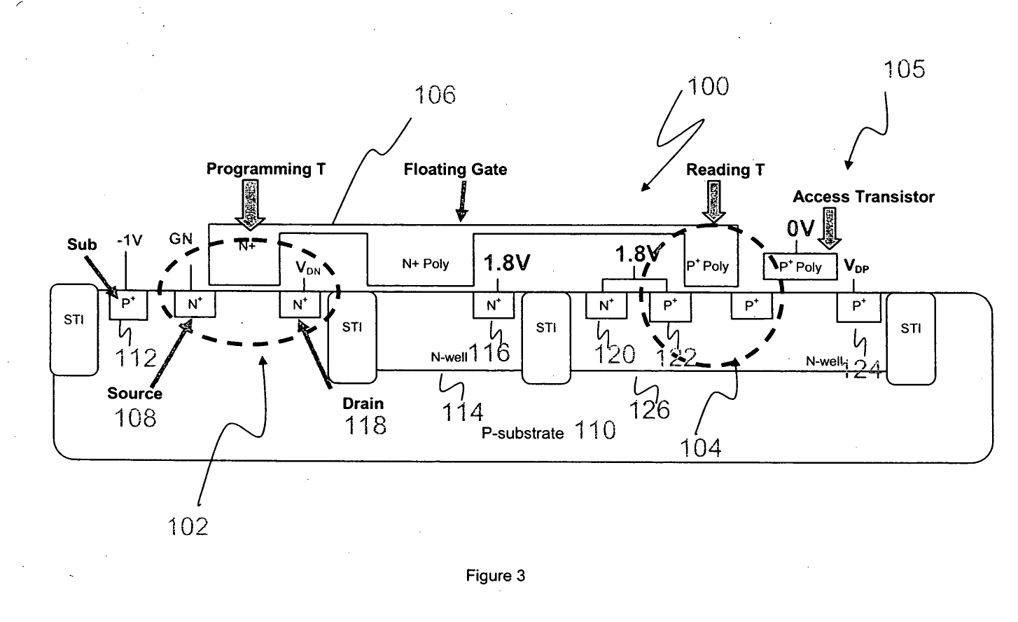

The plots shown in FIG. 2 were obtained from measurements at the nMOS 102 (FIG. 1) directly, i.e. they were not obtained from an actual reading configuration of the OTP cell 100 (FIG. 1) in a read mode. With reference to FIG. 3, which shows a schematic cross-sectional drawing of the OTP cell 100 in a read configuration, in the read mode, a current source (not shown) and a sense amplifier (not shown) are used to detect the state of the pMOS 104. During drawing of a sense current through the pMOS 104 transistor, the state of the pMOS 104 can be determined by measuring the current at the drain 124 of an access transistor 105 of the OTP cell 100 where V_{DP} is at 0V. In the read configuration illustrated in FIG. 3 for an example configuration, the n-well 114 pick-up 116, the n-well 126 pick-up 120, and the source 122 of the pMOS 102 are at 1.8V. The gate 128 of the access transistor 105 is at 0V. As will be appreciated by a person skilled in the art, if the pMOS 104 is on, i.e. corresponding to the nMOS 102 being programmed, a non-zero current value will be measured or detected at the drain 124 of the access transistor 105. Conversely, if the pMOS 104 is off, corresponding to the nMOS 102 being un-programmed or erased, no current signal will be detected at the drain 124 of the access transistor 105. A programmed cell gives an output of one, and an un-programmed cell gives an output of zero.

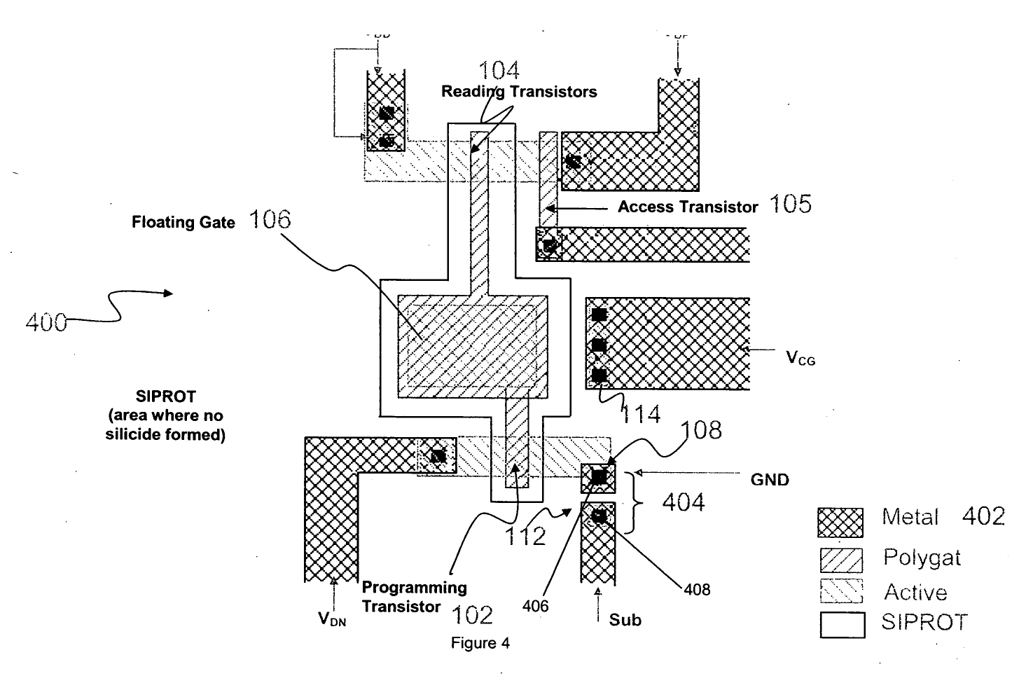

FIG. 4 shows an overview 400 of an OTP cell design in an example embodiment. In FIG. 4, the same numerals for the corresponding components compared with the schematic drawings in FIGS. 1 and 3 have been used for easy comparison and understanding.

Importantly, in the design 400, the M1 layer 402 design includes a disconnection pattern 404, separating the contact 406 to the source 108 of nMOS 102 and the contact 408 to the p-bulk 110 of the substrate via p⁺ region 112. This advantageously facilitates separate biasing for CHISEL programming, as discussed above.

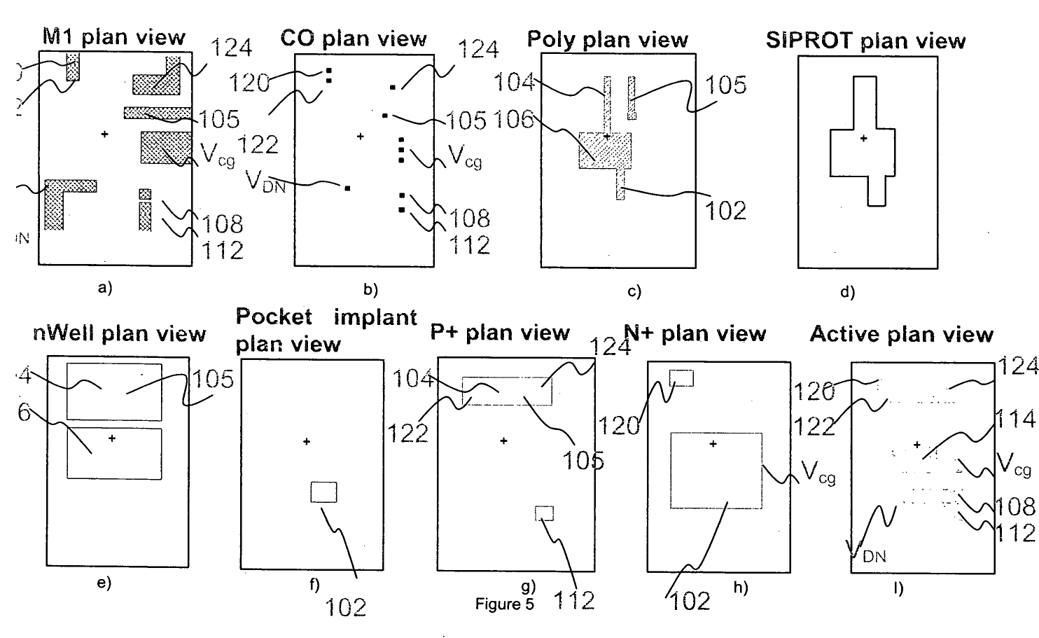

FIGS. 5a to i show the mask layer layouts for the OTP cell structure of FIG. 4. More particular, FIG. 5a shows the mask layer layouts for the metal 1 (M1) mask layer plan view, FIG. 5b shows the contact (CO) mask layer plan view, FIG. 5c shows the Polysilicon (POLY) mask layer plan view, and FIG. 5d shows the Silicide protection (SIPROT) mask layer plan view. FIG. 5e shows the n-well mask layer plan view, FIG. 5f shows the tilted or Pocket implantation mask layer plan view, FIG. 5g shows the p⁺ mask layer plan view, FIG. 5h shows the n⁺ mask layer plan view, and FIG. 5i shows the active mask layer plan view, i.e. the mask layer used to distinguish the shallow-trench isolation (STI) regions. In FIGS. 5a to i, the same numerals have been used to indicate corresponding components from the schematic drawings in FIGS. 1 and 3, for easy comparison and understanding. In FIG. 5b, it will be appreciated that the numerals indicated for the respective contact portions have been shown to illustrate the corresponding components of the schematic drawings in FIGS. 1 and 3 to which the respective contacts make contact to.

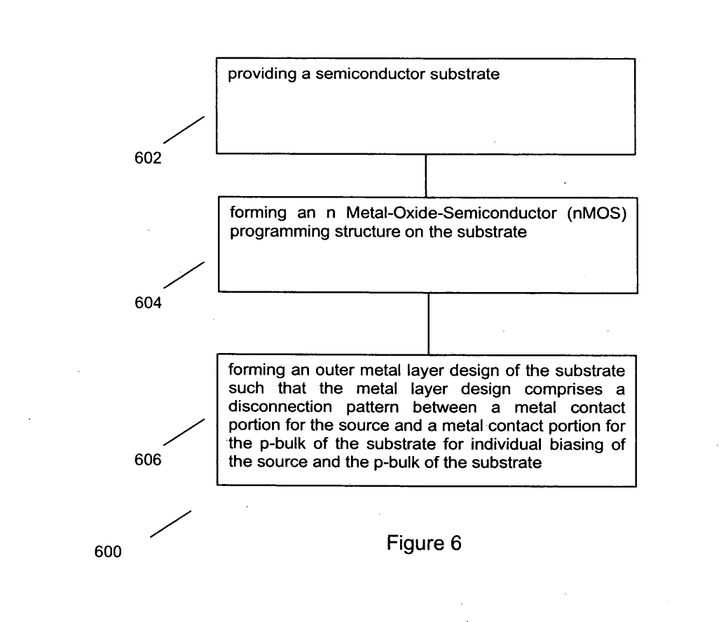

FIG. 6 shows a flowchart 600 illustrating a method of fabricating a One Time Programming (OTP) cell structure according to an example embodiment. At step 602, a semiconductor substrate is provided. At step 604, an n Metal-Oxide-Semiconductor (nMOS) programming structure is provided on the substrate. At step 606, an outer metal layer design of the substrate is formed such that the metal layer design comprises a disconnection pattern between a metal contact portion for the source and a metal contact portion for the p-bulk of the substrate for individual biasing of the source and the p-bulk of the substrate.

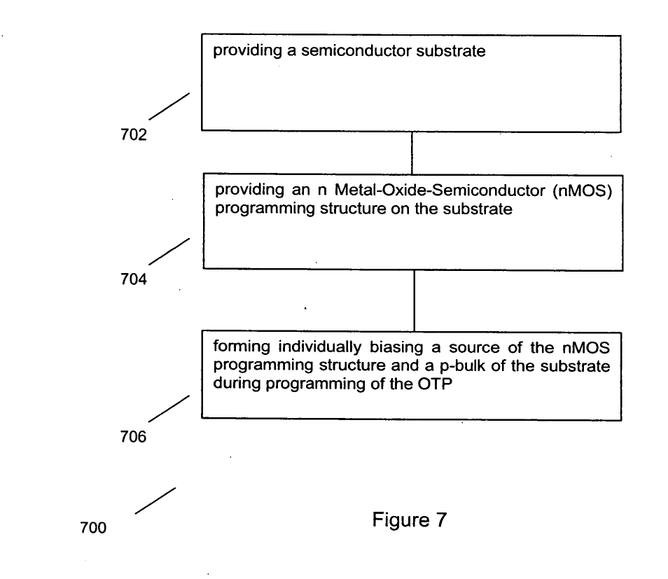

FIG. 7 shows a flowchart 700 illustrating a method of programming a One Time Programming (OTP) cell structure according to an example embodiment. At step 702, a semiconductor substrate is provided. At step 704, an n Metal-Oxide-Semiconductor (nMOS) programming structure is provided on the substrate. At step 706, a source of the nMOS programming structure and a p-bulk of the substrate are individually biased during programming of the OTP.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

1. A One Time Programming (OTP) cell structure comprising:
a semiconductor substrate;
an n Metal-Oxide-Semiconductor (nMOS) programming structure formed on the substrate;
wherein respective electrical contacts to a source of the nMOS programming structure and to a p-bulk of the substrate are separated for individual biasing of the source and the p-bulk of the substrate.

2. The OTP cell structure as claimed in claim 1, wherein the nMOS programming structure includes Halo implantation for enhancing Channel Initiated Secondary Electron (CHISEL) programming of the OTP cell structure.

3. The OTP cell structure as claimed in claim 1, wherein an outer metal layer design of the substrate comprises a disconnection pattern between a metal contact portion for the source and a metal contact portion for the p-bulk of the substrate.

4. The OTP cell structure as claimed in claim 2, wherein the source of the nMOS programming structure is at ground potential.

5. The OTP cell structure as claimed in claim 4, wherein the p-bulk of the substrate is at a negative potential.

6. The OTP cell structure as claimed in claim 5, wherein a threshold voltage of the nMOS programming structure of the OTP cell, in a programmed state, at a drain voltage of about 0.1V is greater than about 3.5V for a programming gate voltage of about 5.25V, a programming drain voltage of about 4.25V, and a programming biasing voltage applied to the p-bulk of the substrate of about −1V, during programming of the nMOS programming structure.

7. The OTP structure as claimed in claim 6, wherein the threshold voltage is about 3.85V.

8. A method of fabricating a One Time Programming (OTP) cell structure, the method comprising the steps of:
providing a semiconductor substrate;
forming an n Metal-Oxide-Semiconductor (nMOS) programming structure on the substrate; and
forming an outer metal layer design of the substrate such that the metal layer design comprises a disconnection pattern between a metal contact portion for the source and a metal contact portion for the p-bulk of the substrate for individual biasing of the source and the p-bulk of the substrate.

9. The method as claimed in claim 8, further comprising performing Halo implantation of the nMOS programming structure for enhancing Channel Initiated Secondary Electron (CHISEL) programming of the OTP cell structure.

10. A method of programming a One Time Programming (OTP) cell structure, the method comprising the steps of:
providing a semiconductor substrate;
providing an n Metal-Oxide-Semiconductor (nMOS) programming structure on the substrate; and
individually biasing a source of the nMOS programming structure and a p-bulk of the substrate during programming of the OTP.

11. The method as claimed in claim 10, further comprising performing Halo implantation of the nMOS programming structure for enhancing Channel Initiated Secondary Electron (CHISEL) programming of the OTP cell structure.
